(19) United States
(12) Patent Application Publication
(10) Pub. No.: US 2014/0209766 A1
(43) Pub. Date: Jul. 31, 2014

(54) RETAINING APPARATUS FOR EXPANSION CARDS

(71) Applicant: HON HAI PRECISION INDUSTRY CO., LTD., New Taipei (TW)

(72) Inventors: YU-SHUN CHANG, New Taipei (TW); HSUAN-CHANG CHEN, New Taipei (TW); CHUNG-PING LIU, New Taipei (TW)

(73) Assignee: HON HAI PRECISION INDUSTRY CO., LTD., New Taipei (TW)

(21) Appl. No.: 13/953,930

(22) Filed: Jul. 30, 2013

(30) Foreign Application Priority Data
Jan. 29, 2013 (CN) 2013100328153

(51) Int. Cl. H05K 13/04; F16M 13/02

(52) U.S. Cl. CPC H05K 13/04; F16M 13/02
USPC 248/201

(57) ABSTRACT

A retaining apparatus includes a first bracket, a second bracket, and an operation member. The first bracket includes two sidewalls. The second bracket includes two side plates slidably attached to the sidewalls, respectively. The operation member includes an operation portion, a mounting piece fixed to the second sidewall, and an engaging piece. A flange extends from one of the side plates of the second bracket. When the second bracket and the first bracket slide toward each other, the engaging piece abuts against a first end of the flange. The operation portion is pressed inward to release the engaging piece from the flange, and the second bracket is slid out relative to the first bracket until the engaging piece is restored to abut against a second end of the flange.

### BACKGROUND

1. Technical Field

The disclosure relates to retaining apparatuses and, more particularly, to a retaining apparatus for mounting expansion cards.

2. Description of Related Art

Expansion cards having different sizes are generally installed in a chassis of an electronic device, such as a computer or a server, with a retaining apparatus receiving the expansion cards. However, each type of retaining apparatus is uniquely designed for a expansion cards of a particular size only.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a retaining apparatus for an expansion card.

FIG. 2 is an assembled, isometric view of the retaining apparatus of FIG. 1.

FIG. 3 is a cutaway view of FIG. 2.

FIG. 4 is an assembled, isometric view of the retaining apparatus of FIG. 1, together with a first expansion card.

FIG. 5 is an assembled, isometric view of the retaining apparatus of FIG. 1, together with a second expansion card.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one.”

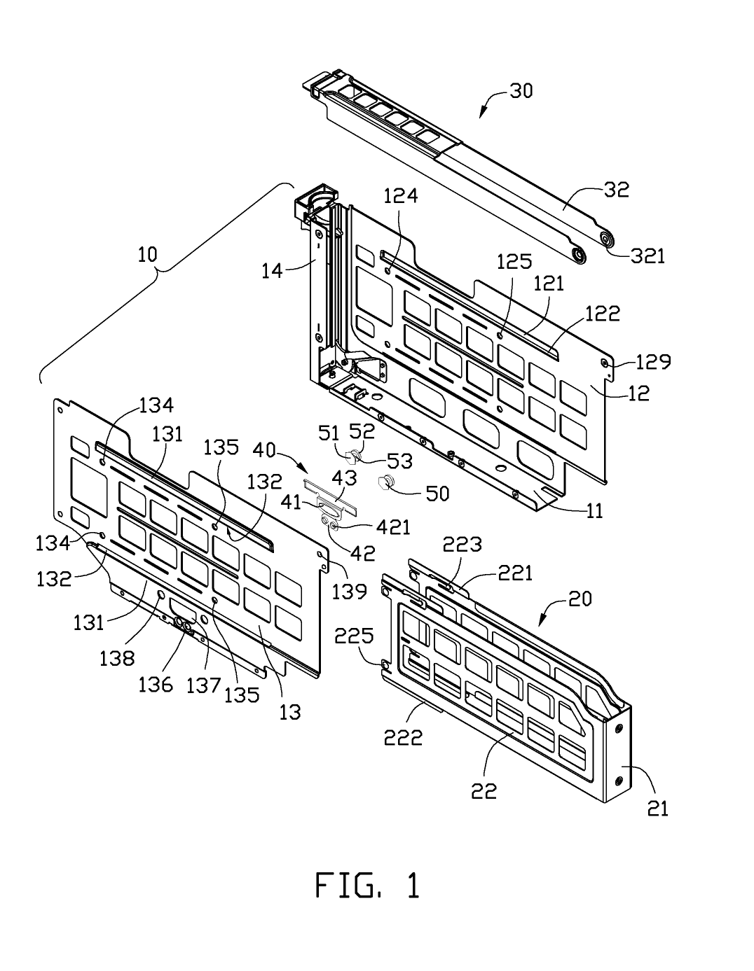

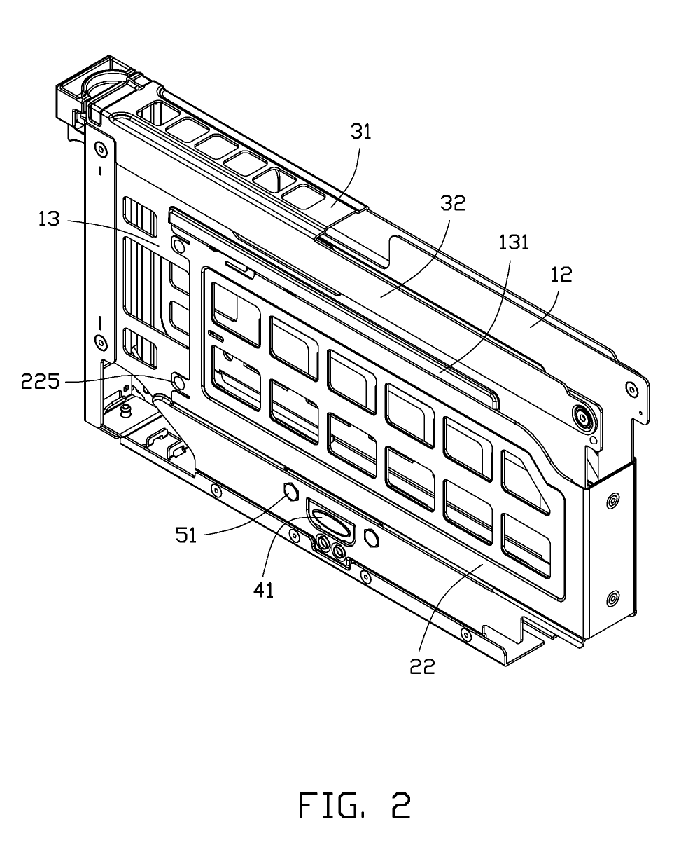

Referring to FIGS. 1 and 2, an exemplary embodiment of a retaining apparatus includes a first bracket 10, a second bracket 20, a retaining member 30, an operation member 40, and two limiting members 50.

The first bracket 10 includes a bottom wall 11, a first sidewall 12 perpendicularly extending up from a first side of the bottom wall 11, a second sidewall 13 detachably fixed to a second side of the bottom wall 11 and parallel to the first sidewall 12, and an end wall 14 extending up from an end of the bottom wall 11 and connected between the first and second sidewalls 12 and 13. Two horizontal first bars 121 protrude from an upper portion and a lower portion of the first sidewall 12, respectively. A first slide slot 122 is defined in each first bar 121. The first sidewall 12 defines two first positioning holes 124 adjacent to the end wall 14, and two second positioning holes 125 away from the end wall 14. The first sidewall 12 defines a pivot hole 129 in an upper corner away from the end wall 14. The bottom wall 11 supports a circuit board (not shown in figures) for connecting an expansion card.

Two horizontal second bars 131 protrude from an upper portion and a lower portion of the second sidewall 13, respectively. A second slide slot 132 is defined in each second bar 131. The second sidewall 13 defines two first positioning holes 134 adjacent to the end wall 14, and two second positioning holes 135 away from the end wall 14. Two fixing holes 136 are defined in a middle of a lower portion of the second sidewall 13. A substantially rectangular through hole 137 is defined in the second sidewall 13 and above the fixing holes 136. Two mounting holes 138 are defined in the second sidewall 13 at opposite sides of the through hole 137. The second sidewall 13 defines a pivot hole 139 in an upper corner away from the end wall 14, and the pivot hole 139 aligns with the pivot hole 129.

The second bracket 20 is substantially U-shaped and includes an end plate 21 and two side plates 22 perpendicularly extending from opposite sides of the end plate 21. A first flange 221 and a second flange 222 extend out from two opposite sides respectively of a first end of each side plate 22 away from the end plate 21. Each first flange 221 defines a through slot and forms a resilient piece 223 in the through slot. Two raised positioning portions 225 respectively extend from an upper portion and a lower portion of the first end of each side plate 22.

The retaining member 30 includes a main plate 31 defining a plurality of vents, and two bar-shaped connecting arms 32 connected substantially perpendicularly to opposite sides of the main plate 31. The connecting arms 32 each form a pivot portion 321 away from the main plate 31.

The operation member 40 includes an operation portion 41, a mounting piece 42 extending down from a bottom of the operation portion 41, and an engaging piece 43 extending up from a top of the operation portion 41. Two columnar pins 421 are formed on the mounting piece 42.

The limiting members 50 each are substantially dumbbell-shaped and include a mounting end 51, a limiting end 52, and a connecting pole 53 connected between the mounting end 51 and the limiting end 52.

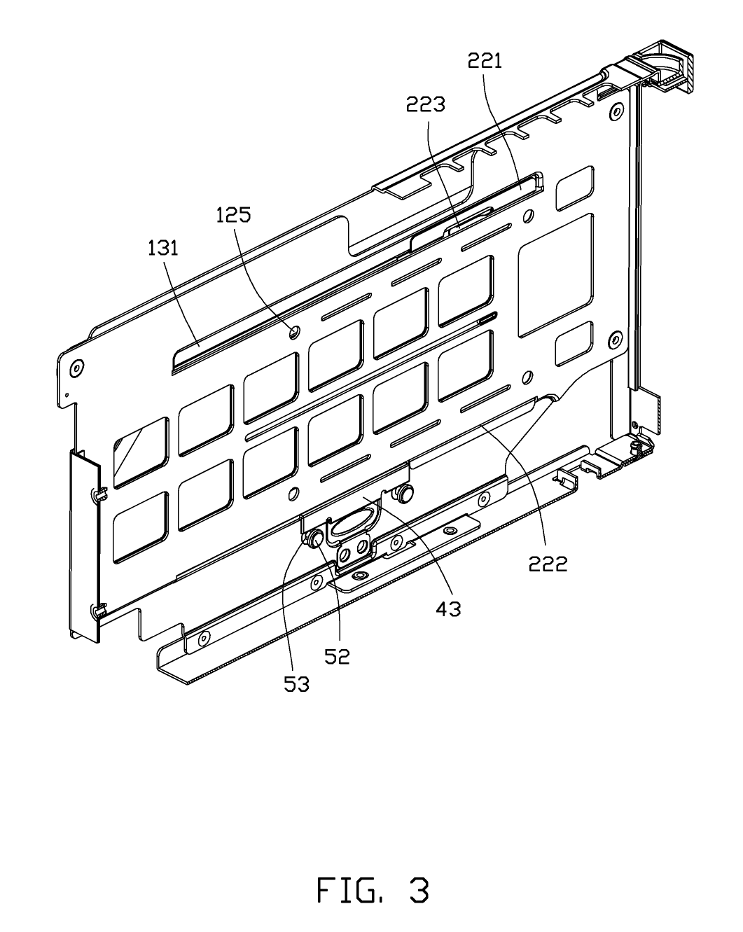

Referring to FIGS. 2 and 3, in assembly, the pins 421 are fixed to the fixing holes 136 to fix the operation member 40 to an inner surface of the second sidewall 13 facing the first sidewall 12. The operation portion 41 is exposed out of the second sidewall 13 through the through hole 137. The engaging piece 43 contacts an inner surface of the second sidewall 13. The mounting ends 51 of the limiting members 50 are fixed in the mounting holes 138 to fix the limiting members 50 to the inner surface of the second sidewall 13. The engaging portion 43 is limited between the inner surface of the second sidewall 13 and the limiting ends 52.

The side plates 22 sandwich the first bracket 10. The first flanges 221 and the second flanges 222 are slidably inserted into the first slide slots 122 and the second slide slots 132. The resilient pieces 223 abut against outer surfaces of the first sidewall 12 and the second sidewall 13.

The pivot portions 321 are pivotably received in the pivot hole 129 and the pivot hole 139. The connecting arms 32 contact with outer surfaces of the first sidewall 12 and the second sidewall 13. One end of the main plate 31 away from the pivot portions 321 is detachably locked to a top of the end wall 14 by a hook and a locking hole structure (not shown in figures).

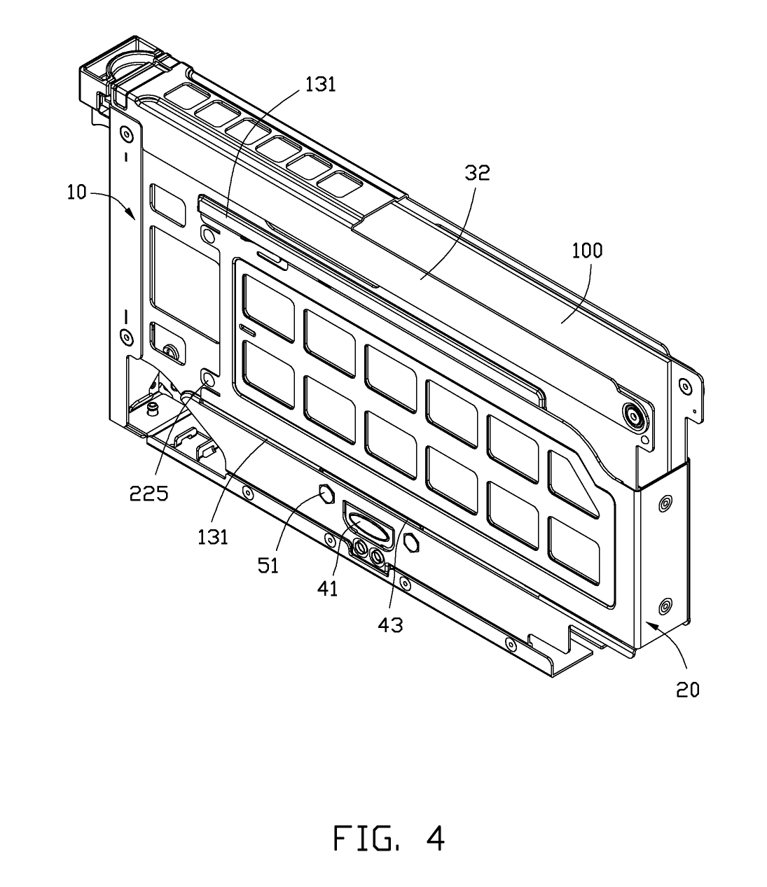

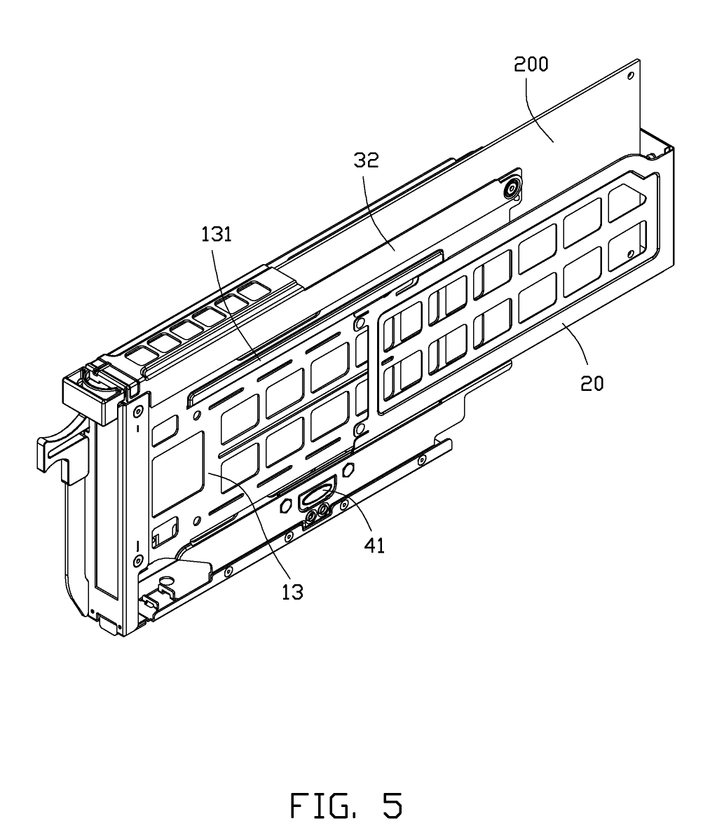

Referring to FIG. 4 and FIG. 5, when mounting a first expansion card 100, the first bracket 10 and the second bracket 20 are slid toward each other. The first flanges 221 and the second flanges 222 slide in the first slide slots 122 and the second slide slots 132, respectively, until the first flanges 221 and the second flanges 222 engage with inner sidewalls bounding the first slide slots 122 and the second slide slots 132 adjacent to the end wall 14. A left end of the engaging portion 43 engages with a right end of one of the second flanges 222 adjacent to the second sidewall 13. The positioning portions 225 engage in the first positioning holes 124 and 134.

When mounting a second expansion card 200, which is greater in length than the first expansion card 100, the operation portion 41 is pressed away from the second sidewall 13 to release the left end of the engaging portion 43 from the right end of the second flange 222, and the first bracket 10 and the second bracket 20 are moved away from each other. The first flanges 221 and the second flanges 222 slide along the first slide slots 122 and the second slide slots 132, until the first flanges 221 and the second flanges 222 engage with inner sidewalls bounding the first slide slots 122 and the second slide slots 132 away from the end wall 14. The operation portion 41 is released, and the engaging portion 43 is restored to contact with the second sidewall 13. A right end of the engaging portion 43 engages with a left end of one of the second flanges 222 adjacent to the second sidewall 13. The positioning portions 225 are received in the second positioning holes 125 and 135. Therefore, the retaining apparatus is adjustable to accommodate expansion cards of different lengths.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A retaining apparatus comprising:
a first bracket comprising a first sidewall and a second sidewall parallel to the first sidewall, the second sidewall defining a slide slot;
a second bracket comprising two side plates parallel to each other, wherein the side plates are slidably attached to the first sidewall and the second sidewall, respectively, one of the side plates forms a flange slidably inserted in the slide slot of the second sidewall; and
an operation member comprising an operation portion, a mounting piece and an engaging portion extending from opposite sides of the operation portion, the mounting piece is fixed to the second sidewall, the engaging portion contacts with an inner surface of the second sidewall facing the first sidewall;
wherein the first bracket and the second bracket are operable to be moved toward each other for retaining a first size expansion card, the flange slides in the slide slot, until the flange engages with a left inner sidewall bounding the slide slot, a left end of the engaging portion engages with a right end of the flange; and
wherein the operation portion is operable to be pressed away from the second sidewall to release the left end of the engaging portion from the right end of the flange, the first bracket and the second bracket are moved away from each other for retaining a second size expansion card greater than the first size expansion card in length, the flange slides in the slide slot until the flange engages with a right inner sidewall bounding the slide slot, the engaging portion is restored to contact with the inner surface of the second sidewall, a left end of the engaging portion engages with a right end of the flange.

2. The retaining apparatus of claim 1, wherein the first bracket further comprises a bottom wall and an end wall extending from an end of the bottom wall, the first sidewall extends from a first side of the bottom wall, the second sidewall is detachably mounted to a second side of the bottom wall.

3. The retaining apparatus of claim 2, further comprising a retaining member, wherein the retaining member comprises a main plate and two bar-shaped connecting arms connected substantially perpendicularly to opposite sides of the main plate, ends of the connecting arms away from the main plate are pivotably connected to upper portions of ends of the first sidewall and the second sidewall away from the end wall, respectively, the connecting arms contact with outer surfaces of the first sidewall and the second sidewall, respectively.

4. The retaining apparatus of claim 2, wherein two horizontal first bars protrude from the first sidewall, two first slide slots are respectively defined in the first bars, two horizontal second bars protrude from the second sidewall respectively, two second slide slots are respectively defined in the second bars, a first flange and a second flange extend out from two opposite sides of a first end of each side plate, the first flanges and the second flanges are slidably inserted into the first slide slots and the second slide slots, respectively, the flange is one of the second flanges formed at a bottom side of one of the side plates contacting with the second sidewall, the slide slot of the second sidewall is a lower one of the second slide slots.

5. The retaining apparatus of claim 4, wherein the first flanges each form a resilient piece, the resilient pieces engage with inner surfaces of the first bar and the second bar respectively.

6. The retaining apparatus of claim 4, wherein the first sidewall defines two first positioning holes adjacent to the end wall and two second positioning holes away from the end wall, the second sidewall defines two first positioning holes adjacent to the end wall and two second positioning holes away from the end wall, two raised positioning portions respectively extend from an upper portion and a lower portion of the first end of each side plate away from the end plate, the positioning portions engage in either the first positioning holes of the first and second sidewalls or the second positioning holes of the first and second sidewalls, respectively.

7. The retaining apparatus of claim 1, further comprising a limiting member, wherein the limiting member comprises a mounting end fixed to the second sidewall adjacent to the operation member, a limiting end, and a connecting pole connected between the mounting end and the limiting end, the engaging portion of the operation member is limited between the inner surface of the second sidewall and the limiting ends.

8. The retaining apparatus of claim 1, wherein a through hole is defined in the second sidewall and aligns with the operation portion, the operation portion is exposed out of the second sidewall through the through hole.
